(19) United States
(12) Patent Application Publication
(10) Pub. No.: US 2023/0010887 A1
(43) Pub. Date: Jan. 12, 2023

(54) MEMS MICROPHONE AND METHOD OF MANUFACTURING THE SAME

(71) Applicant: DB HITEK CO., LTD., Seoul (KR)

(72) Inventor: Kyu Hyun KWACK, Seoul (KR)

(21) Appl. No.: 17/810,755

(22) Filed: Jul. 5, 2022

(30) Foreign Application Priority Data
Jul. 6, 2021 (KR) 10-2021-0088308

(51) Int. Cl. H04R 19/04; B81B 3/00; B81C 1/00; H04R 31/00

(52) U.S. Cl. CPC H04R 19/04; B81B 3/007; B81C 1/00658; H04R 31/003; B81B 2201/0257; B81B 2203/0127; B81B 2203/019; B81B 2203/0307; B81B 2203/04; H04R 2201/003

(57) ABSTRACT

A MEMS microphone includes a substrate having a cavity, a diaphragm disposed above the substrate to correspond to the cavity, and a back plate disposed above the diaphragm. The diaphragm has a plurality of grooves for adjusting an elastic strength of the diaphragm.

### CROSS-REFERENCE TO RELATED APPLICATION

This application claims the priority benefit of Korean Patent Application No. 10-2021-0088308, filed on Jul. 6, 2021, and all the benefits accruing therefrom under 35 U.S.C. §119, the contents of which are incorporated by reference in their entirety.

### TECHNICAL FIELD

The present disclosure relates to a MEMS (Micro-Electro Mechanical System) microphone and a method of manufacturing the same. More specifically, the present disclosure relates to a MEMS microphone capable of converting a sound into an acoustic signal using a diaphragm configured to be vibrated by a sound pressure and a method of manufacturing the same.

### BACKGROUND

A MEMS microphone may be used to convert a sound into an acoustic signal and may be manufactured by a MEMS technology. For example, the MEMS microphone may include a diaphragm disposed above a substrate and a back plate disposed above the diaphragm. The diaphragm and the back plate may be supported by a plurality of anchors on the substrate, and a predetermined air gap may be provided between the diaphragm and the back plate.

The diaphragm may include a lower conductive layer used as a lower electrode, and the back plate may include an upper conductive layer used as an upper electrode, and an insulating layer formed on the upper conductive layer to support the upper conductive layer. The diaphragm may be vibrated by an applied sound pressure, whereby the air gap between the diaphragm and the back plate may be changed. Further, a capacitance between the diaphragm and the back plate may be changed by the change in the air gap, and the acoustic signal may be detected from the change in the capacitance.

The sensitivity of the MEMS microphone may be proportional to the capacitance between the diaphragm and the back plate and may be inversely proportional to the elastic strength of the diaphragm. However, when the size of the MEMS microphone is reduced, the elastic strength of the diaphragm may increase and, accordingly, the sensitivity of the MEMS microphone may be reduced.

### SUMMARY

The present disclosure provides a MEMS microphone capable of adjusting an elastic strength of a diaphragm and a method of manufacturing the same.

In accordance with an aspect of the present disclosure, a MEMS microphone may include a substrate having a cavity, a diaphragm disposed above the substrate to correspond to the cavity, and a back plate disposed above the diaphragm. Particularly, the diaphragm may have a plurality of grooves for adjusting an elastic strength of the diaphragm.

In accordance with some embodiments of the present disclosure, the diaphragm may include a lower electrode layer having a disk shape, a strength control region configured to surround the lower electrode layer, and a first anchor portion configured to surround the strength control region and to fix the diaphragm on the substrate. In such cases, the grooves may be formed in surface portions of the strength control region.

In accordance with some embodiments of the present disclosure, each of the grooves may have a channel shape extending in a circumferential direction.

In accordance with some embodiments of the present disclosure, each of the grooves may have a circular shape.

In accordance with some embodiments of the present disclosure, the grooves may include a plurality of first grooves having a channel shape extending in a circumferential direction, and a plurality of second grooves having a channel shape extending in a radial direction. In such cases, the second grooves may be disposed among the first grooves.

In accordance with some embodiments of the present disclosure, the grooves may include a plurality of first grooves having a channel shape extending in a circumferential direction, and a plurality of second grooves having a circular shape. In such cases, the second grooves may be disposed between the lower electrode layer and the first grooves.

In accordance with some embodiments of the present disclosure, the diaphragm may have a plurality of ventilation holes that pass through the strength control region and are arranged in a circumferential direction. In such cases, the grooves may be disposed between the lower electrode layer and the ventilation holes.

In accordance with another aspect of the present disclosure, a method of manufacturing a MEMS microphone may include forming a diaphragm above a substrate, forming a plurality of grooves in surface portions of the diaphragm to adjust an elastic strength of the diaphragm, forming a back plate above the diaphragm, and forming a cavity through the substrate to expose a lower surface of the diaphragm.

In accordance with some embodiments of the present disclosure, the forming the diaphragm may include forming a lower insulating layer on a substrate, forming a lower silicon layer on the lower insulating layer, and forming a portion of the lower silicon layer into a lower electrode layer by performing an ion implantation process.

In accordance with some embodiments of the present disclosure, the forming the diaphragm may further include forming a first anchor channel partially exposing the substrate by partially removing the lower insulating layer. In such cases, a portion of the lower silicon layer formed in the first anchor channel may function as a first anchor portion for fixing the diaphragm on the substrate.

In accordance with some embodiments of the present disclosure, the first anchor channel may be formed to surround the lower electrode layer, another portion of the lower silicon layer between the lower electrode layer and the first anchor portion may function as a strength control region, and the grooves may be formed in surface portions of the strength control region.

In accordance with some embodiments of the present disclosure, the lower electrode layer may be formed to have a disk shape, and each of the grooves may be formed to have a channel shape extending in a circumferential direction or a circle shape.

In accordance with some embodiments of the present disclosure, the grooves may include a plurality of first grooves having a channel shape extending in a circumferential direction and a plurality of second grooves having a channel shape extending in a radial direction. In such cases, the second grooves may be formed among the first grooves.

In accordance with some embodiments of the present disclosure, the grooves may include a plurality of first grooves having a channel shape extending in a circumferential direction and a plurality of second grooves having a circular shape and formed between the lower electrode layer and the first grooves.

In accordance with some embodiments of the present disclosure, the forming the diaphragm may further include forming a plurality of ventilation holes passing through the strength control region and arranged in a circumferential direction. In such cases, the grooves may be formed between the lower electrode layer and the ventilation holes.

In accordance with the embodiments of the present disclosure as described above, the elastic strength of the diaphragm may be reduced by forming the grooves in surface portions of the diaphragm. In addition, the size and number of the grooves may be appropriately adjusted according to the size of the diaphragm, thereby significantly improving the sensitivity of the MEMS microphone.

The above summary of the present disclosure is not intended to describe each illustrated embodiment or every implementation of the present disclosure. The detailed description and claims that follow more particularly exemplify these embodiments.

### BRIEF DESCRIPTION OF THE DRAWINGS

Embodiments can be understood in more detail from the following description taken in conjunction with the accompanying drawings, in which:

FIG. 1 is a schematic plan view illustrating a MEMS microphone in accordance with an embodiment of the present disclosure;

FIG. 2 is a schematic cross-sectional view taken along a line I-I′ as shown in FIG. 1;

FIG. 3 is a schematic enlarged cross-sectional view illustrating grooves as shown in FIG. 2;

FIG. 4 is a schematic plan view illustrating the grooves as shown in FIG. 2;

FIG. 5 is a schematic plan view illustrating another example of the grooves as shown in FIG. 4;

FIG. 6 is a schematic plan view illustrating still another example of the grooves as shown in FIG. 4;

FIG. 7 is a schematic plan view illustrating still another example of the grooves as shown in FIG. 4;

FIG. 8 is a flowchart illustrating a method of manufacturing the MEMS microphone as shown in FIGS. 1 and 2; and

FIGS. 9 to 23 are schematic cross-sectional views illustrating the method of manufacturing the MEMS microphone as shown in FIG. 8.

While various embodiments are amenable to various modifications and alternative forms, specifics thereof have been shown by way of example in the drawings and will be described in detail. It should be understood, however, that the intention is not to limit the claimed inventions to the particular embodiments described. On the contrary, the intention is to cover all modifications, equivalents, and alternatives falling within the spirit and scope of the subject matter as defined by the claims.

### DETAILED DESCRIPTION

Hereinafter, embodiments of the present invention are described in more detail with reference to the accompanying drawings. However, the present invention is not limited to the embodiments described below and is implemented in various other forms. Embodiments below are not provided to fully complete the present invention but rather are provided to fully convey the range of the present invention to those skilled in the art.

In the specification, when one component is referred to as being on or connected to another component or layer, it can be directly on or connected to the other component or layer, or an intervening component or layer may also be present. Unlike this, it will be understood that when one component is referred to as directly being on or directly connected to another component or layer, it means that no intervening component is present. Also, though terms like a first, a second, and a third are used to describe various regions and layers in various embodiments of the present invention, the regions and the layers are not limited to these terms.

Terminologies used below are used to merely describe specific embodiments, but do not limit the present invention. Additionally, unless otherwise defined here, all the terms including technical or scientific terms, may have the same meaning that is generally understood by those skilled in the art.

Embodiments of the present invention are described with reference to schematic drawings of ideal embodiments. Accordingly, changes in manufacturing methods and/or allowable errors may be expected from the forms of the drawings. Accordingly, embodiments of the present invention are not described being limited to the specific forms or areas in the drawings, and include the deviations of the forms. The areas may be entirely schematic, and their forms may not describe or depict accurate forms or structures in any given area and are not intended to limit the scope of the present invention.

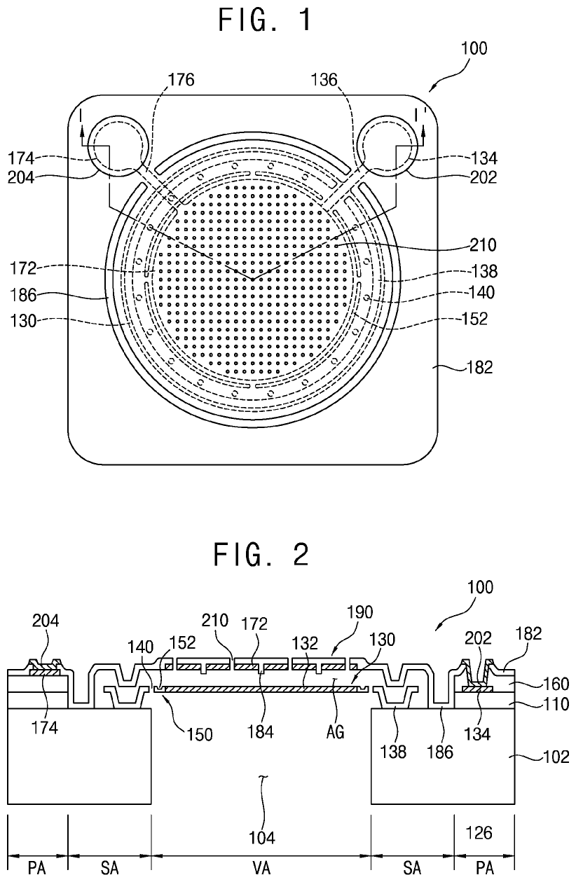

FIG. 1 is a schematic plan view illustrating a MEMS microphone in accordance with an embodiment of the present disclosure. FIG. 2 is a schematic cross-sectional view taken along a line I-I′ as shown in FIG. 1.

Referring to FIGS. 1 and 2, a MEMS microphone 100, in accordance with an embodiment of the present disclosure, may include a substrate 102 having a cavity 104, a diaphragm 130 disposed above the substrate 102 to correspond to the cavity 104, and a back plate 190 disposed above the diaphragm 130.

In embodiments, the substrate 102 may be a single-crystal silicon substrate and may include a vibration area (VA), a support area (SA) surrounding the vibration area (VA), and a periphery area (PA) surrounding the support area (SA). In such cases, the cavity 104 may be formed to pass through the vibration area (VA), and the diaphragm 130 may be exposed through the cavity 104.

In accordance with an embodiment of the present disclosure, the diaphragm 130 may have a plurality of grooves 152 for adjusting an elastic strength of the diaphragm 130 and may be spaced apart from the substrate 102 to be vibrated by an applied sound pressure. In embodiments, the diaphragm 130 may include a lower electrode layer 132 made of a conductive material and having a disk shape, and a first anchor portion 138 configured to surround the lower electrode layer 132 and to fix the lower electrode layer 132 on the substrate 102. In embodiments, the lower electrode layer 132 may be made of polysilicon doped with impurities, and the first anchor portion 138 may be made of undoped polysilicon. Further, the first anchor portion 138 may have a ring shape surrounding the lower electrode layer 132 and may be formed on the support area (SA) of the substrate 102. Particularly, the diaphragm 130 may include a strength control region 150 having a circular ring shape to surround the lower electrode layer 132, and the first anchor portion 138 may have a circular ring shape surrounding the strength control region 150. In accordance with an embodiment of the present disclosure, the grooves 152 may be formed in upper surface portions of the strength control region 150.

Further, the diaphragm 130 may include a first electrode pad 134 electrically connected to the lower electrode layer 132. In embodiments, the first electrode pad 134 may be connected to the lower electrode layer 132 by a first connection pattern 136 as shown in FIG. 1. In this case, the first electrode pad 134 and the first connection pattern 136 may be made of the same material as the lower electrode layer 132.

The back plate 190 may include a support layer 182 made of an insulating material, and an upper electrode layer 172 attached to a lower surface of the support layer 182 and made of a conductive material. In particular, the back plate 190 may be disposed above the diaphragm 130 so that the upper electrode layer 172 is spaced apart from the lower electrode layer 132 by a predetermined distance. That is, a predetermined air gap (AG) may be provided between the lower electrode layer 132 and the upper electrode layer 172. In embodiments, the upper electrode layer 172 may be made of polysilicon doped with impurities, and the support layer 182 may be made of silicon nitride.

In addition, the back plate 190 may include a second anchor portion 186 for fixing the support layer 182 on the substrate 102, and a second electrode pad 174 electrically connected to the upper electrode layer 172. In embodiments, as shown in FIG. 2, the second anchor portion 186 may be disposed on the support area (SA) of the substrate 102 and may be made of silicon nitride. The upper electrode layer 172 and the second electrode pad 174 may be electrically connected by a second connection pattern 176 as shown in FIG. 1. Further, the second electrode pad 174 and the second connection pattern 176 may be formed of the same material as the upper electrode layer 172.

The first anchor portion 138 may have a circular ring shape surrounding the cavity 104, and the second anchor portion 186 may have a circular ring shape surrounding the first anchor portion 138. Further, between the lower electrode layer 132 and the first anchor portion 138, a plurality of ventilation holes 140 for connecting the air gap (AG) between the diaphragm 130 and the back plate 190 with an inner space of the cavity 104 may be formed through the diaphragm 130. In embodiments, the ventilation holes 140 may pass through the strength control region 150 and may be arranged in a circumferential direction.

A lower insulating layer 110 may be disposed on an upper surface of the substrate 102, and an upper insulating layer 160 may be disposed on the lower insulating layer 110. In this case, the first electrode pad 134 may be disposed on the lower insulating layer 110, and the second electrode pad 174 may be disposed on the upper insulating layer 160. In embodiments, the lower insulating layer 110 and the upper insulating layer 160 may be made of silicon oxide and may be formed to surround the second anchor portion 186.

A first bonding pad 202 may be disposed on the first electrode pad 134, and a second bonding pad 204 may be disposed on the second electrode pad 174. In embodiments, as shown in FIG. 18, a first contact hole (CH1) exposing the first electrode pad 134 may be formed through the support layer 182 and the upper insulating layer 160, and the first bonding pad 202 may be formed in the first contact hole (CH1). Further, a second contact hole (CH2) exposing the second electrode pad 174 may be formed through the support layer 182 and the second bonding pad 204 may be formed in the second contact hole (CH2). In addition, the support layer 182 may include protrusions 184 penetrating through the upper electrode layer 172 and protruding toward the lower electrode layer 132. The protrusions 184 may be made of the same material as the support layer 182 and may be used to prevent the lower electrode layer 132 and the upper electrode layer 172 from contacting each other.

Further, referring back to FIG. 2, the back plate 190 may have a plurality of air holes 210 connected to the air gap (AG). The air holes 210 may be formed through the support layer 182 and the upper electrode layer 172. In embodiments, the air holes 210 may be disposed among the protrusions 184.

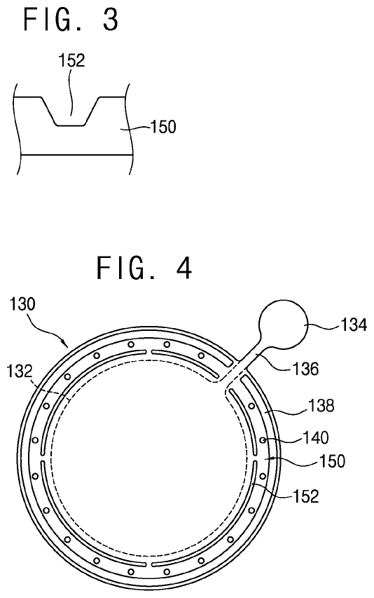

FIG. 3 is a schematic enlarged cross-sectional view illustrating grooves as shown in FIG. 2. FIG. 4 is a schematic plan view illustrating the grooves as shown in FIG. 2.

Referring to FIGS. 3 and 4, the grooves 152 may be used to adjust the elastic strength of the diaphragm 130. In embodiments, each of the grooves 152 may have a channel shape extending in the circumferential direction and may be formed in upper surface portions of the strength control region 150 between the lower electrode layer 132 and the ventilation holes 140. In particular, the grooves 152 may have inclined inner surfaces to prevent stress concentration. Further, corner portions of the grooves 152 may have a curved shape to prevent stress concentration.

In accordance with an embodiment of the present disclosure, the grooves 152 may reduce the elastic strength of the diaphragm 130, thereby improving the sensitivity of the MEMS microphone 100. In addition, the width, length, and number of the grooves 152 may be appropriately adjusted to improve the sensitivity of the MEMS microphone 100.

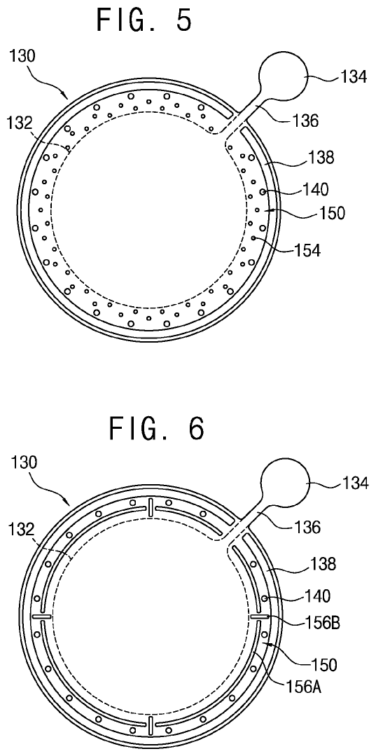

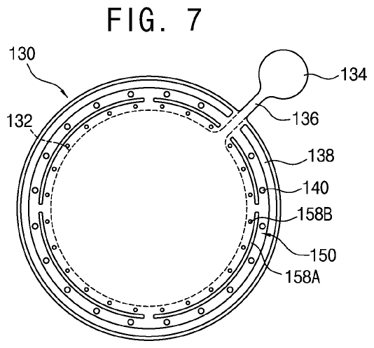

FIG. 5 is a schematic plan view illustrating another example of the grooves as shown in FIG. 4. FIG. 6 is a schematic plan view illustrating still another example of the grooves as shown in FIG. 4. FIG. 7 is a schematic plan view illustrating still another example of the grooves as shown in FIG. 4.

Referring to FIG. 5, the diaphragm 130 may have a plurality of grooves 154 formed in upper surface portions of the strength control region 150 and having a circular shape. In this case, the size and number of the grooves 154 may be appropriately adjusted to improve the sensitivity of the MEMS microphone 100.

Referring to FIG. 6, the diaphragm 130 may include a plurality of first grooves 156A formed in upper surface portions of the strength control region 150 and having a channel shape extending in a circumferential direction, and a plurality of second grooves 156B formed in upper surface portions of the strength control region 150 and having a channel shape extending in a radial direction. In such cases, the second grooves 156B may be disposed among the first grooves 156A.

Referring to FIG. 7, the diaphragm 130 may include a plurality of first grooves 158A formed in upper surface portions of the strength control region 150 and having a channel shape extending in a circumferential direction, and a plurality of second grooves 158B formed in upper surface portions of the strength control region 150 and having a circular shape. In such cases, the second grooves 158B may be disposed between the lower electrode layer 132 and the first grooves 158A.

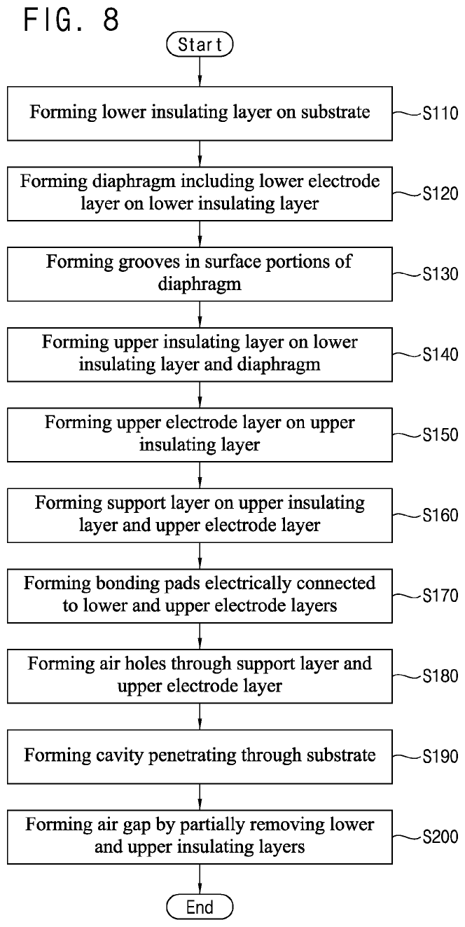

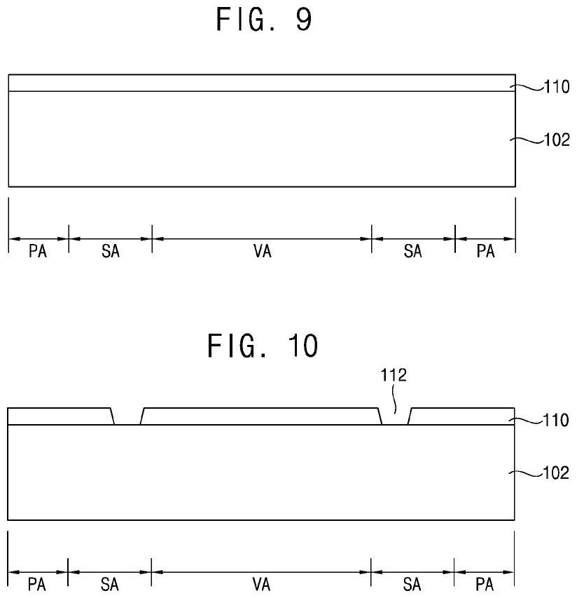

FIG. 8 is a flowchart illustrating a method of manufacturing the MEMS microphone as shown in FIGS. 1 and 2. FIGS. 9 to 23 are schematic cross-sectional views illustrating the method of manufacturing the MEMS microphone as shown in FIG. 8.

Referring to FIGS. 8 and 9, in step S110, a lower insulating layer 110 may be formed on a substrate 102. In embodiments, the substrate 102 may be a silicon wafer and the lower insulating layer 110 may be made of an insulating material, such as silicon oxide. The lower insulating layer 110 may be formed conformally, that is, to have an approximately uniform thickness through a chemical vapor deposition process.

Referring to FIG. 8, in step S120, a diaphragm 130 including a lower electrode layer 132 may be formed on the lower insulating layer 110. Specifically, as shown in FIG. 10, the lower insulating layer 110 may be patterned to form a first anchor channel 112 exposing a surface portion of the substrate 102. The substrate 102 may include a vibration area (VA), a support area (SA) surrounding the vibration area (VA), and a periphery area (PA) surrounding the support area (SA), and the first anchor channel 112 may be formed on the support area (SA). In particular, the first anchor channel 112 may have a circular ring shape surrounding the vibration region (VA). In embodiments, after forming a photoresist pattern exposing a portion where the first anchor channel 112 is to be formed on the lower insulating layer 110, an etching process using the photoresist pattern as an etching mask may be performed, whereby the first anchor channel 112 may be formed to expose a portion of the upper surface of the substrate 102.

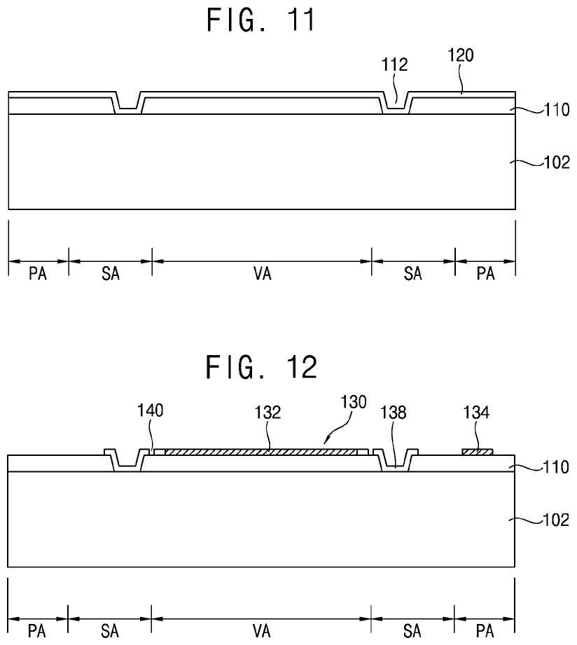

Referring to FIG. 11, after forming the first anchor channel 112, a lower silicon layer 120 may be conformally formed on the lower insulating layer 110 to have an approximately uniform thickness. In embodiments, the lower silicon layer 120 may be a polysilicon layer formed by a chemical vapor deposition process. In such cases, a portion of the lower silicon layer 120 formed in the first anchor channel 112 may be used as a first anchor portion 138 for fixing a diaphragm 130 to be formed subsequently on the substrate 102.

Referring to FIG. 12, an ion implantation process may be performed to form a portion of the lower silicon layer 120 into a lower electrode layer 132 having conductivity. Further, a first electrode pad 134 and a first connection pattern 136 (refer to FIG. 1) for connecting the lower electrode layer 132 and the first electrode pad 134 may be formed in the lower silicon layer 120 by the ion implantation process. In embodiments, the lower electrode layer 132 may have a disk shape and may be disposed above the vibration region (VA).

Then, the lower silicon layer 120 may be patterned to form a diaphragm 130 including the lower electrode layer 132, the first electrode pad 134, and the first connection pattern 136. In addition, a first anchor portion 138 for fixing the diaphragm 130 on the substrate 102 may be formed on the portion of the substrate 102 exposed by the first anchor channel 112, and a plurality of ventilation holes 140 may be formed between the lower electrode layer 132 and the first anchor portion 138. In embodiments, a photoresist pattern covering portions where the lower electrode layer 132, the first anchor portion 138, the first electrode pad 134, and the first connection pattern 136 are to be formed may be formed on the lower silicon layer 120. Next, an etching process, using the photoresist pattern as an etching mask, may be performed until the lower insulating layer 110 is exposed.

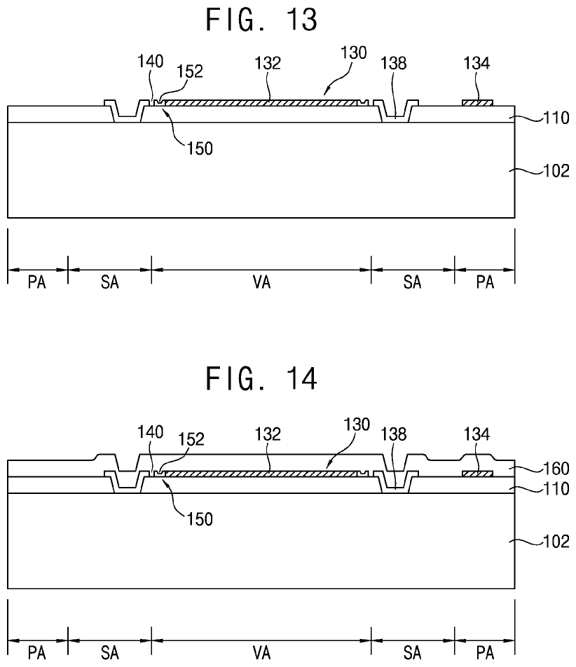

Referring to FIGS. 8 and 13, in step S130, a plurality of grooves 152 for adjusting the elastic strength of the diaphragm 130 may be formed in surface portions of the diaphragm 130. In embodiments, after forming a photoresist pattern exposing portions where the grooves 152 are to be formed on the diaphragm 130, an anisotropic etching process, using the photoresist pattern as an etch mask, may be performed in order to form the grooves 152 for a predetermined time.

As an example, the lower electrode layer 132 may have a disk shape, and the grooves 152 may be formed in upper surface portions of a strength control region 150 having a circular ring shape surrounding the lower electrode layer 132. In this case, the first anchor portion 138 may have a circular ring shape surrounding the strength control region 150. In addition, the ventilation holes 140 may be formed through the strength control region 150, and the grooves 152 may be formed between the lower electrode layer 132 and the ventilation holes 140. In particular, as shown in FIG. 3, the grooves 152 may have inclined inner surfaces and corner portions of the grooves 152 may have a curved shape to prevent stress concentration. Further, as shown in FIG. 4, the grooves 152 may have a channel shape extending in a circumferential direction.

As another example, as shown in FIG. 5, a plurality of circular grooves 154 may be formed in upper surface portions of the strength control region 150. As still another example, as shown in FIG. 6, a plurality of first grooves 156A having a channel shape extending in a circumferential direction and a plurality of second grooves 156B having a channel shape extending in a radial direction may be formed in upper surface portions of the strength control region 150. In this case, the second grooves 156B may be formed among the first grooves 156A. As still another example, as shown in FIG. 7, a plurality of first grooves 158A having a channel shape extending in a circumferential direction and a plurality of second grooves 158B having a circular shape may be formed in upper surface portions of the strength control region 150. In this case, the second grooves 158B may be formed between the lower electrode layer 132 and the first grooves 158A.

Referring to FIGS. 8 and 14, in step S140, an upper insulating layer 160 may be formed on the lower insulating layer 110 and the diaphragm 130. In embodiments, the upper insulating layer 160 may include silicon oxide and may be formed conformally, that is, to have an approximately uniform thickness by a chemical vapor deposition process.

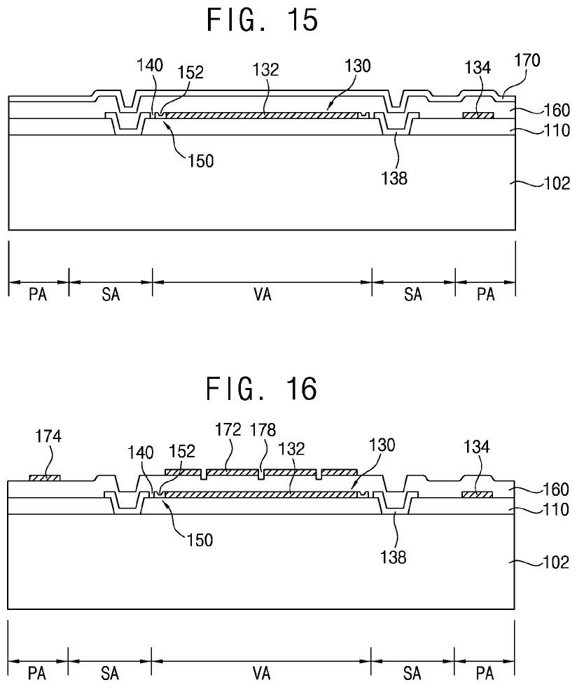

Referring to FIG. 8, in step S150, an upper electrode layer 172 may be formed on the upper insulating layer 160. In embodiments, as shown in FIG. 15, an upper silicon layer 170 may be conformally formed on the upper insulating layer 160 to have an approximately uniform thickness. In embodiments, the upper silicon layer 170 may be a polysilicon layer formed by a chemical vapor deposition process. Subsequently, an ion implantation process may be performed to form the upper silicon layer 170 into a conductive layer (not shown), that is, a polysilicon layer doped with impurities.

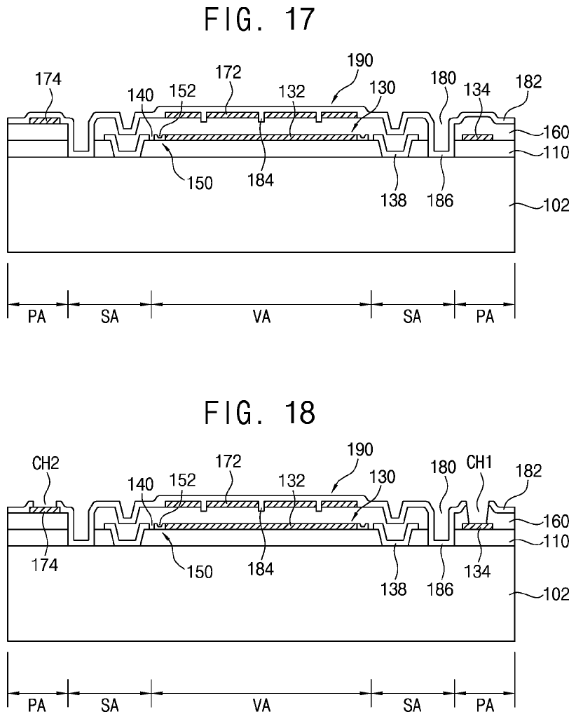

Referring to FIG. 16, the conductive layer may be patterned to form an upper electrode layer 172 corresponding to the lower electrode layer 132, a second electrode pad 174, and a second connection pattern 176 (refer to FIG. 1) for connecting the upper electrode layer 172 and the second electrode pad 174. That is, as shown in FIG. 16, the remaining portions of the conductive layer excluding the upper electrode layer 172, the second electrode pad 174, and the second connection pattern 176 may be removed. In embodiments, a photoresist pattern may be formed on the conductive layer to cover regions where the upper electrode layer 172, the second electrode pad 174, and the second connection pattern 176 are to be formed. Next, an etching process, using the photoresist pattern as an etching mask, may be performed until the upper insulating layer 160 is exposed.

Then, a plurality of holes 178 for forming protrusions 184 (refer to FIG. 2) extending toward the lower electrode layer 132 may be formed by removing portions of the upper electrode layer 172 and the upper insulating layer 160. The holes 178 may have a predetermined depth in order to extend through the upper electrode layer 172 to a portion of the upper insulating layer 160. In embodiments, after forming a photoresist pattern exposing portions where the holes 178 are to be formed on the upper electrode layer 172, an anisotropic etching process, using the photoresist pattern as an etching mask, may be performed for a predetermined time.

Referring to FIGS. 8 and 17, in step S160, a support layer 182 may be formed on the upper insulating layer 160 and the upper electrode layer 172. In embodiments, the upper insulating layer 160 and the lower insulating layer 110 may be patterned to form a second anchor channel 180 having a circular ring shape surrounding the first anchor portion 138. In embodiments, a photoresist pattern exposing portions where the second anchor channel 180 is to be formed may be formed on the upper insulating layer 160. Next, an anisotropic etching process, using the photoresist pattern as an etching mask, may be performed until the upper surface of the substrate 102 is exposed.

After the second anchor channel 180 is formed, a support layer 182 may be conformally formed on the upper electrode layer 172 and the upper insulating layer 160 to have an approximately uniform thickness. As a result, a back plate 190 including the upper electrode layer 172 and the support layer 182 may be formed above the substrate 102. In embodiments, the support layer 182 may be a silicon nitride layer formed by a chemical vapor deposition process. In particular, the support layer 182 may be formed to fill the holes 178, whereby protrusions 184 extending downward from the support layer 182 through the upper electrode layer 172 may be formed. In addition, a portion of the support layer 182 formed in the second anchor channel 180 may be used as a second anchor portion 186 for fixing the support layer 182 on the substrate 102.

Referring to FIG. 8, in step S170, bonding pads 202 and 204 may be formed, which may be electrically connected to the lower electrode layer 132 and the upper electrode layer 172. Specifically, as shown in FIG. 18, a first contact hole (CH1) may be formed by patterning the support layer 182 and the upper insulating layer 160, exposing the first electrode pad 134. In addition, a second contact hole (CH2) may be formed by patterning the support layer 182, exposing the second electrode pad 174. In embodiments, after forming a photoresist pattern exposing portions of the support layer 182, corresponding to the first electrode pad 134 and the second electrode pad 174 on the support layer 182, the first contact hole (CH1) and the second contact hole (CH2) may be formed by an anisotropic etching process using the photoresist pattern as an etching mask.

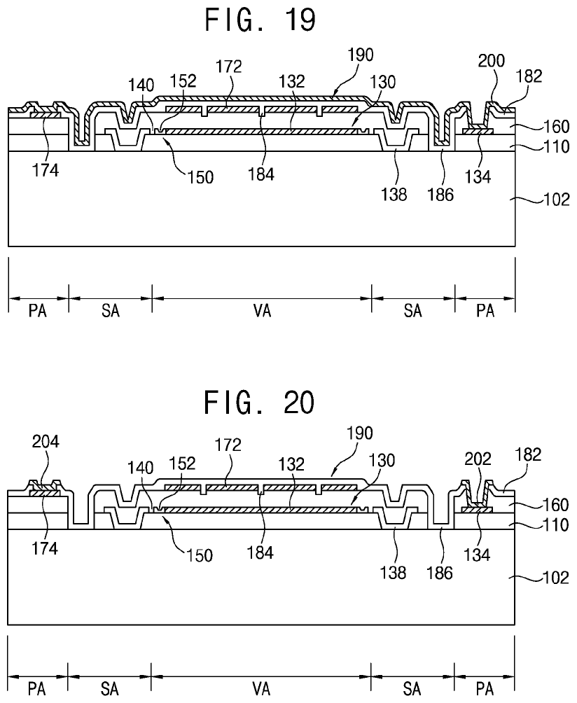

Subsequently, as shown in FIGS. 19 and 20, a first bonding pad 202 and a second bonding pad 204 may be formed on the first electrode pad 134 and the second electrode pad 174, respectively. In embodiments, the first bonding pad 202 and the second bonding pad 204 may be made of a metal such as aluminum and may be formed by forming an aluminum layer 200 on the support layer 182 and then patterning the aluminum layer 200.

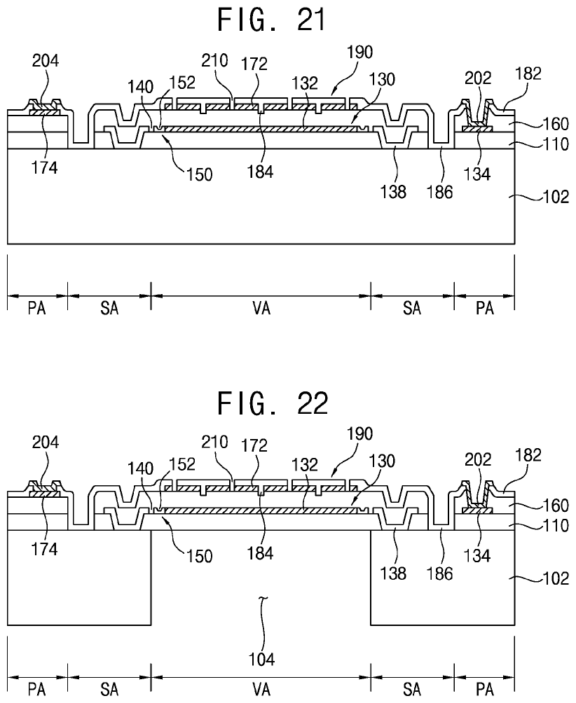

Referring to FIGS. 8 and 21, in step S180, the support layer 182 and the upper electrode layer 172 may be patterned to form a plurality of air holes 210. In embodiments, after forming a photoresist pattern exposing portions where the air holes 210 are to be formed on the support layer 182, the air holes 210 may be formed by an anisotropic etching process using the photoresist pattern as an etching mask.

Referring to FIGS. 8 and 22, in step S190, a cavity 104 penetrating through the substrate 102 may be formed. In embodiments, a back grinding process may be performed to reduce the thickness of the substrate 102, and then a cavity 104 penetrating the substrate 102 may be formed. In this case, the cavity 104 may be formed to correspond to the diaphragm 130 and to expose the lower insulating layer 110 by an anisotropic etching process.

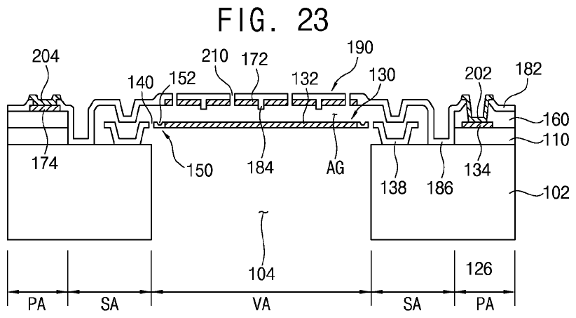

Referring to FIGS. 8 and 23, in step S200, an air gap (AG) may be formed by partially removing the lower insulating layer 110 and the upper insulating layer 160. In embodiments, a portion of the lower insulating layer 110 and a portion of the upper insulating layer 160, formed inside the second anchor portion 186, may be removed by an etching process. In such cases, an etching solution or an etching gas may be supplied between the diaphragm 130 and the back plate 190 through the air holes 210 and the ventilation holes 140. As a result, the diaphragm 130 may be exposed downwardly through the cavity 104 and the air gap (AG) may be formed between the diaphragm 130 and the back plate 190.

In accordance with the embodiments of the present disclosure as described above, the elastic strength of the diaphragm 130 may be reduced by forming the grooves 152 in surface portions of the diaphragm 130. In addition, the size and number of the grooves 152 may be appropriately adjusted according to the size of the diaphragm 130, thereby significantly improving the sensitivity of the MEMS microphone 100.

Although the example embodiments of the present disclosure have been described with reference to the specific embodiments, they are not limited thereto. Therefore, it will be readily understood by those skilled in the art that various modifications and changes can be made thereto without departing from the spirit and scope of the present disclosure defined by the appended claims.

What is claimed is:

1. A MEMS microphone comprising:
a substrate having a cavity;
a diaphragm disposed above the substrate to correspond to the cavity; and
a back plate disposed above the diaphragm,
wherein the diaphragm has a plurality of grooves for adjusting an elastic strength of the diaphragm.

2. The MEMS microphone of claim 1, wherein the diaphragm comprises:
a lower electrode layer having a disk shape;
a strength control region configured to surround the lower electrode layer; and
a first anchor portion configured to surround the strength control region and to fix the diaphragm on the substrate,
wherein the grooves are formed in surface portions of the strength control region.

3. The MEMS microphone of claim 2, wherein each of the grooves has a channel shape extending in a circumferential direction.

4. The MEMS microphone of claim 2, wherein each of the grooves has a circular shape.

5. The MEMS microphone of claim 2, wherein the grooves comprises;
a plurality of first grooves having a channel shape extending in a circumferential direction; and
a plurality of second grooves having a channel shape extending in a radial direction.

6. The MEMS microphone of claim 5, wherein the second grooves are disposed among the first grooves.

7. The MEMS microphone of claim 2, wherein the grooves comprises:
a plurality of first grooves having a channel shape extending in a circumferential direction; and
a plurality of second grooves having a circular shape.

8. The MEMS microphone of claim 7, wherein the second grooves are disposed between the lower electrode layer and the first grooves.

9. The MEMS microphone of claim 2, wherein the diaphragm has a plurality of ventilation holes that pass through the strength control region and are arranged in a circumferential direction.

10. The MEMS microphone of claim 9, wherein the grooves are disposed between the lower electrode layer and the ventilation holes.

11. A method of manufacturing a MEMS microphone, the method comprising:
forming a diaphragm above a substrate;
forming a plurality of grooves in surface portions of the diaphragm to adjust an elastic strength of the diaphragm;
forming a back plate above the diaphragm; and
forming a cavity through the substrate to expose a lower surface of the diaphragm.

12. The method of claim 11, wherein the forming the diaphragm comprises:
forming a lower insulating layer on a substrate;
forming a lower silicon layer on the lower insulating layer; and
forming a portion of the lower silicon layer into a lower electrode layer by performing an ion implantation process.

13. The method of claim 12, wherein the forming the diaphragm further comprises:
forming a first anchor channel partially exposing the substrate by partially removing the lower insulating layer,
wherein a portion of the lower silicon layer formed in the first anchor channel functions as a first anchor portion for fixing the diaphragm on the substrate.

14. The method of claim 13, wherein the first anchor channel is formed to surround the lower electrode layer;
another portion of the lower silicon layer between the lower electrode layer and the first anchor portion functions as a strength control region; and
the grooves are formed in surface portions of the strength control region.

15. The method of claim 14, wherein the lower electrode layer is formed to have a disk shape, and
each of the grooves is formed to have a channel shape extending in a circumferential direction or a circle shape.

16. The method of claim 14, wherein the lower electrode layer is formed to have a disk shape, and
the grooves comprises a plurality of first grooves having a channel shape extending in a circumferential direction and a plurality of second grooves having a channel shape extending in a radial direction.

17. The method of claim 16, wherein the second grooves are formed among the first grooves.

18. The method of claim 14, wherein the lower electrode layer is formed to have a disk shape, and
the grooves comprises a plurality of first grooves having a channel shape extending in a circumferential direction and a plurality of second grooves having a circular shape and formed between the lower electrode layer and the first grooves.

19. The method of claim 14, wherein the forming the diaphragm further comprises:
forming a plurality of ventilation holes passing through the strength control region and arranged in a circumferential direction.

20. The method of claim 19, wherein the grooves are formed between the lower electrode layer and the ventilation holes.
